(19) United States
(12) Patent Application Publication
(10) Pub. No.: US 2025/0359443 A1
(43) Pub. Date: Nov. 20, 2025

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yi HE, Beijing (CN); Rong WANG, Beijing (CN); Jia LIU, Beijing (CN); Jun YAN, Beijing (CN); Fan HE, Beijing (CN); Xiangdan DONG, Beijing (CN); Hanchao LI, Beijing (CN); Hui GUAN, Beijing (CN); Xin ZHOU, Beijing (CN)

(21) Appl. No.: 18/860,636

(22) PCT Filed: Nov. 10, 2023
(86) PCT No.: PCT/CN2023/130948

§ 371 Date: Aug. 8, 2025

(30) Foreign Application Priority Data
Dec. 1, 2022 (CN) 202211533619.X

(51) Int. Cl. H10K 59/131; H10K 59/95

(52) U.S. Cl. CPC H10K 59/131; H10K 59/95

(57) ABSTRACT

A display substrate, including: a base substrate, multiple sub-pixels, multiple data lines, multiple test circuit groups, multiple aging pin groups and multiple binding pin groups. The base substrate includes a display area and a binding area. The multiple sub-pixels are in the display area. The multiple data lines are electrically connected to the multiple sub-pixels. The multiple test circuit groups are arranged along a first direction and electrically connected to the multiple data lines. The multiple aging pin groups and the multiple binding pin groups are in the binding area and on a side of the multiple test circuit groups facing away from the display area. The multiple binding pin groups are arranged along the first direction, and at least one aging pin group is arranged between every two adjacent binding pin groups. Each binding pin group is configured to be bonded and connected to at least one circuit board.

The present application claims priority to Chinese Patent Application No. 202211533619.X, filed to the CNIPA on Dec. 1, 2022 and entitled “Display substrate and display apparatus”, the contents of which should be construed as being incorporated herein by reference.

### TECHNICAL FIELD

The present disclosure relates to, but is not limited to, the field of display technologies, in particular to a display substrate and a display apparatus.

### BACKGROUND

An Organic Light Emitting Diode (OLED) and a Quantum dot Light Emitting Diode (QLED) are active light emitting display apparatuses and have advantages of self-luminescence, wide viewing angle, high contrast ratio, low power consumption, very high response speed, lightness and thinness, bendability, and a low cost, etc.

### SUMMARY

The following is a summary of subject matter described herein in detail. This summary is not intended to limit the protection scope of claims.

Embodiments of the present disclosure provide a display substrate and a display apparatus.

In one aspect, embodiments of the present disclosure provide a display substrate including a base substrate, a plurality of sub-pixels, a plurality of data lines, a plurality of test circuit groups, a plurality of aging pin groups, and a plurality of bonding pin groups. The base substrate includes a display area and a bonding area on one side of the display area. The plurality of sub-pixels are located in the display area. The plurality of data lines are located in the display area and the bonding area, and the plurality of data lines are electrically connected to the plurality of sub-pixels. The plurality of test circuit groups are arranged along a first direction, and the plurality of test circuit groups are electrically connected to the plurality of data lines. The plurality of aging pin groups and the plurality of bonding pin groups are located in the bonding area and on a side of the plurality of test circuit groups away from the display area. The plurality of bonding pin groups are arranged along the first direction, and at least one aging pin group is arranged between two adjacent bonding pin groups. Each bonding pin group is configured to be bonded to at least one circuit board. Each test circuit group is configured to be connected to at least one aging pin group during the test stage.

In some exemplary embodiments, the plurality of bonding pin groups includes n bonding pin groups, with n being a positive integer greater than or equal to 3, and the plurality of bonding pin groups includes a first bonding pin group, a second bonding pin group, and an n-th bonding pin group sequentially along the first direction. An aging pin group included between the first bonding pin group and the second bonding pin group includes a plurality of first aging pins arranged along the first direction continuously and configured to transmit a gate drive control signal. An aging pin group included between the n-th bonding pin group and the (n-1)-th bonding pin group includes a plurality of first aging pins arranged along the first direction continuously and configured to transmit a gate drive control signal.

In some exemplary embodiments, the display substrate further includes a bezel area located at a remaining side of the display area; wherein the bezel area is provided with a gate drive circuit configured to be connected to the first aging pins in the aging pin group between the first bonding pin group and the second bonding pin group and the aging pin group between the n-th bonding pin group and the (n-1)-th bonding pin group during the test stage.

In some exemplary embodiments, one or two aging pin groups are provided between two adjacent bonding pin groups.

In some exemplary embodiments, each of the plurality of aging pin groups includes a plurality of second aging pins arranged along the first direction continuously and configured to transmit a direct current signal.

In some exemplary embodiments, at least one aging pin group of the plurality of aging pin groups includes a plurality of first aging pins arranged along the first direction continuously and configured to transmit a gate drive control signal and a plurality of second aging pins arranged along the first direction continuously and configured to transmit a direct current signal, and the plurality of second aging pins are located on one side of the plurality of first aging pins close to an edge of the display substrate.

In some exemplary embodiments, a first aging pin of at least one aging pin group of the plurality of aging pin groups is configured to be electrically connected to a first aging pin transmitting a same signal in other aging pin groups during the test stage.

In some exemplary embodiments, second aging pins transmitting a same signal in the plurality of aging pin groups are configured to be electrically connected during the test stage.

In some exemplary embodiments, the plurality of test circuit groups are connected by a test circuit connection line.

In some exemplary embodiments, at least one test circuit group of the plurality of test circuit groups is configured to be connected to two aging pin groups during the test stage, and the two aging pin groups are located on two sides of the at least one test circuit group.

In some exemplary embodiments, pins transmitting a same signal in aging pin groups electrically connected to different test circuit groups and arranged adjacent to each other are configured to be electrically connected during the test stage.

In some exemplary embodiments, pins transmitting a same signal in aging pin groups electrically connected to a same test circuit group and arranged adjacent to each other are configured to be electrically connected during the test stage.

In some exemplary embodiments, the plurality of aging pin groups are arranged along the first direction, and the plurality of aging pin groups and the plurality of bonding pin groups are arranged side by side along the first direction.

In some exemplary embodiments, each of the plurality of bonding pin groups includes a plurality of access pins, at least one first power supply pin, and at least one second power supply pin arranged along the first direction. The at least one first power supply pin and the at least one second power supply pin in each bonding pin group are configured to be used as aging pins during an aging stage, and each bonding pin group is configured to be bonded to at least one circuit board after the aging stage.

In another aspect, an embodiment of the present disclosure provides a display apparatus, which includes the aforementioned display substrate.

In another aspect, an embodiment of the present disclosure provide a display substrate, including a base substrate, a plurality of sub-pixels, a plurality of data lines, a plurality of driver chip pin groups, a plurality of aging pin groups, and a plurality of bonding pin groups. The base substrate includes a display area and a bonding area on a side of the display area. The plurality of sub-pixels are located in the display area. The plurality of data lines are located in the display area and the bonding area, and the plurality of data lines are electrically connected to the plurality of sub-pixels. A plurality of driver chip pin groups are located in the bonding area and arranged along a first direction, connected with a plurality of data lines, and the plurality of driver chip pin groups are configured to be bonded to a driver chip. A plurality of aging pin groups and a plurality of bonding pin groups are located in the bonding area and at a side of the plurality of driver chip pin groups away from the display area, and the plurality of bonding pin groups are arranged along the first direction and connected with the plurality of driver chip pin groups through pin connection lines. At least one aging pin group is arranged between two adjacent bonding pin groups.

In some exemplary embodiments, the plurality of aging pin groups are arranged along the first direction, and the plurality of aging pin groups and the plurality of bonding pin groups are arranged side by side along the first direction.

In some exemplary embodiments, the plurality of bonding pin groups and the plurality of driver chip pin groups are correspondingly in one-to-one electrical connection.

In some exemplary embodiments, the plurality of driver chip pin groups include m driver chip pin groups, with m being a positive integer greater than or equal to 3, and the plurality of driver chip pin groups includes a first driver chip pin group, a second driver chip pin group, and an m-th driver chip pin group in the first direction. The display substrate further includes a bezel area located at a remaining side of the display area, the bezel area is provided with a gate drive circuit configured to be electrically connected with the first driver chip pin group and the m-th driver chip pin group through a first signal transmission line.

In some exemplary embodiments, one or two aging pin groups are provided between two adjacent bonding pin groups.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a structure of a display apparatus.

FIG. 2 is a schematic plan view of a display substrate.

FIG. 3 is a schematic diagram of a partial sectional structure of a display area of a display substrate.

FIG. 4 is a schematic diagram showing an arrangement of a plurality of display substrates included in a display mother plate.

FIG. 5 is a schematic view of a bonding area of a display substrate according to at least one embodiment of the present disclosure.

FIG. 6 is a partial schematic view of a display mother plate according to at least one embodiment of the present disclosure.

FIG. 7A is a schematic diagram illustrating local distribution of an aging pin group 31g and a bonding pin group 41a in FIG. 6.

FIG. 7B is a schematic diagram illustrating the local distribution of an aging pin group 31h and a bonding pin group 41d in FIG. 6.

FIGS. 8A and 8B are partial schematic views of a bonding pin region and a first cutting region of FIG. 6.

FIG. 9A is a schematic diagram of a bonding area of a display substrate according to at least one embodiment of the present disclosure.

FIG. 9B is a partial schematic view of a bonding area of the display substrate in FIG. 9A.

FIG. 10A is a schematic diagram of a bonding area of a display substrate according to at least one embodiment of the present disclosure.

FIG. 10B is a partial schematic view of a bonding area of the display substrate in FIG. 10A.

FIG. 11A is a schematic diagram of a bonding area of a display substrate according to at least one embodiment of the present disclosure.

FIG. 11B is a partial schematic view of a bonding area of the display substrate in FIG. 11A.

FIG. 12A is a schematic diagram of a bonding area of a display substrate according to at least one embodiment of the present disclosure.

FIG. 12B is a partial schematic view of a bonding area of the display substrate in FIG. 12A.

FIG. 13 is an equivalent circuit diagram of a test circuit according to at least one embodiment of the present disclosure.

FIG. 14 is a schematic plan view of a test circuit according to at least one embodiment of the present disclosure.

FIG. 15A is another schematic diagram of local distribution of the aging pin group 31g and the bonding pin group 41a of FIG. 6.

FIG. 15B is another schematic diagram of local distribution of the aging pin group 31h and the bonding pin group 41d of FIG. 6.

FIG. 16 is another partial schematic view of the bonding pin region and the first cutting region of FIG. 6;

FIG. 17 is a schematic view of a bonding area of a display substrate according to at least one embodiment of the present disclosure.

FIG. 18 is a partial schematic view of a display mother plate according to at least one embodiment of the present disclosure.

FIG. 19 is a partial schematic view of a bonding pin region and a first cutting region of FIG. 18.

FIG. 20 is a schematic view of a bonding area of a display substrate according to at least one embodiment of the present disclosure.

FIG. 21 is a partial schematic view of a display mother plate according to at least one embodiment of the present disclosure.

FIG. 22 is a partial schematic view of a bonding pin region and a first cutting region in FIG. 21.

### DETAILED DESCRIPTION

The embodiments of the present disclosure will be described below with reference to the drawings in detail. Implementations may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limitations on numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which are not limited to the expressions in the specification.

In the specification, unless otherwise specified and defined, terms “mounting”, “mutual connection”, and “connection” should be understood in a broad sense. For example, a connection may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of constituent elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain) and the source electrode (source electrode terminal, source electrode region, or source), and a current can flow through the drain electrode, the channel region, and the source electrode. In the specification, the channel region refers to a region through which a current mainly flows.

In the specification, a first electrode may be a drain electrode and a second electrode may be a source electrode, or, a first electrode may be a source electrode and a second electrode may be a drain electrode. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

In the present disclosure, “about” and “substantially” refer to that a boundary is not defined strictly and a case in a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends in in the B direction” in the present disclosure means “the main body portion of A extends along the B direction”.

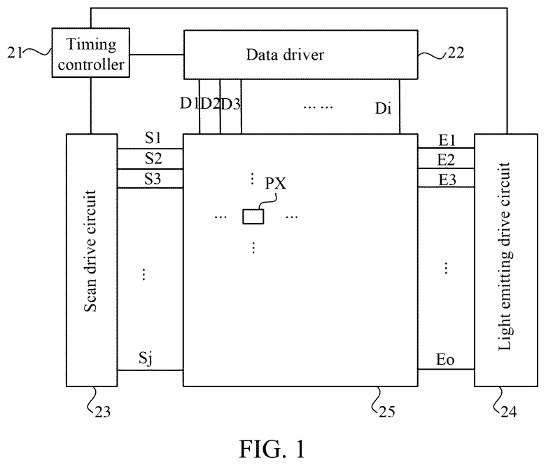

FIG. 1 is a schematic diagram of a structure of a display apparatus. In some examples, as shown in FIG. 1, the display apparatus may include a timing controller 21, a data driver 22, a scan drive circuit 23, a light emitting driver 24, and a sub-pixel array 25. In some examples, the sub-pixel array 25 may include a plurality of sub-pixels PX arranged regularly. The scan drive circuit 23 may be configured to supply a scan signal to a sub-pixel PX along a scan line. The data driver 22 may be configured to supply a data voltage to a sub-pixel PX along a data line. The light emitting drive circuit 24 may be configured to supply a light emitting control signal to a sub-pixel PX along a light emitting control line. The timing controller 21 may be configured to control the scan drive circuit 23, the light emitting drive circuit 24 and the data driver 22.

In some examples, the timing controller 21 may provide the data driver 22 with a gray-scale value and a control signal suitable for a specification of the data driver 22, the timing controller 21 may provide the scan drive circuit 23 with a scan clock signal, a scan start signal, etc., suitable for a specification of the scan driver 23, and the timing controller 21 may provide the light emitting drive circuit 24 with a light emitting clock signal, a light emitting start signal, etc., suitable for a specification of the light emitting drive circuit 24. The data driver 22 may generate a data voltage to be provided to data lines D1 to Di, using the gray-scale value and the control signal received from the timing controller 21. For example, the data driver 22 may sample the gray-scale value using the clock signal and apply a data voltage corresponding to the gray-scale value to the data lines D1 to Di using a sub-pixel row as a unit. The scan circuit 23 may receive the scan clock signal, the scan start signal, etc., from the timing controller 21 to generate a scan signal to be provided to scan lines S1 to Sj. For example, the scan drive circuit 23 may sequentially provide scan signals with on-level pulses to scan lines. In some examples, the scan driver 23 may include a shift register and sequentially transmit the scan start signal provided in form of an on-level pulse to a next-stage circuit to generate the scan signal under control of the scan clock signal. The light emitting drive circuit 24 may receive the light emitting clock signal, the light emitting start signal, etc., from the timing controller 21 to generate a light emitting control signal to be provided to light emitting control lines E1 to Eo. For example, the light emitting drive circuit 24 may provide sequentially light emitting control signals with an off-level pulse to the light emitting control lines. The light emitting drive circuit 24 may include a shift register, and generate a light emitting control signal by sequentially transmitting a light emitting initial signal provided in a form of an off-level pulse to a next-stage circuit under control of the clock signal, where i, j, and o are all natural numbers.

In some examples, the display apparatus may include a display substrate. The scan drive circuit and the light emitting drive circuit may be directly provided on the display substrate. For example, the scan drive circuit may be provided on a left bezel of the display substrate, and the light emitting drive circuit may be provided on a right bezel of the display substrate. Or, each of the left bezel and the right bezel of the display substrate may be provided with a scan drive circuit and a light emitting driving circuit. In some examples, the scan drive circuit and the light emitting drive circuit may be formed together with the sub-pixels in a process of forming the sub-pixels.

In some examples, the data driver may be disposed on an independent chip or printed circuit board to be connected to a sub-pixel through a signal access pin on the display substrate. For example, the data driver may be formed and disposed at a first bezel of the display substrate using a chip on glass, a chip on plastics, a chip on film, etc., to be connected to a signal access pin. The timing controller may be arranged separately from or integrally with the data driver. However, this embodiment is not limited thereto. In some examples, the data driver may be directly disposed on the display substrate.

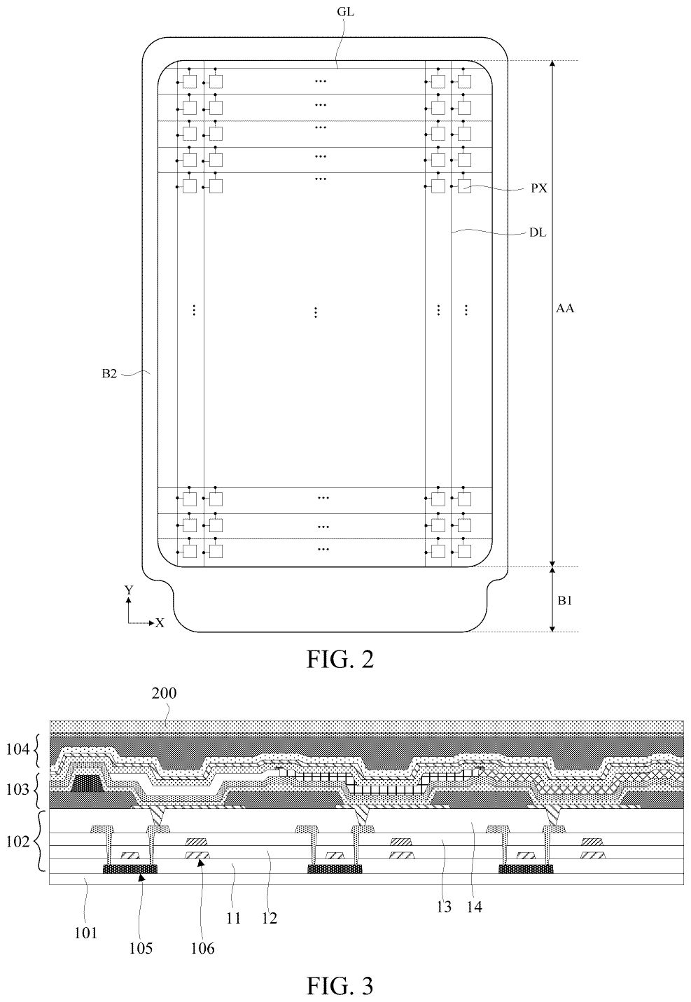

FIG. 2 is a schematic plan view of a display substrate. In some examples, as shown in FIG. 2, the display substrate may include a display area AA, a bonding area B1 located on one side of the display area AA, and a bezel area B2 located on another side of the display area AA. The bonding area B1 may be, for example, a lower bezel of the display substrate, and the bezel area B2 may include an upper bezel, a left bezel, and a right bezel of the display substrate. In some examples, the display area AA may be a flat area including a plurality of sub-pixels PX that form a pixel array, and the plurality of sub-pixels PX are configured to display a dynamic picture or a static image. The display area may be referred to as an effective area. In some examples, the display substrate may be a flexible substrate. Accordingly, the display substrate may be deformable, for example, crimped, bent, folded, or curled.

In some examples, the bezel region area B2 may include a circuit region, a power supply line region, a crack dam region, and a cutting region which are sequentially disposed along a direction of the display area AA. The circuit region may be connected with the display area AA and may at least include multiple cascaded gate drive circuits connected to a plurality of gate lines in the display area AA. The power supply line region is connected to the circuit region and may at least include a low-level power supply line. The low-level power supply line may extend along a direction parallel to an edge of the display area and is connected to a cathode in the display area AA. The crack dam region may be connected to the power supply line region and may at least include a plurality of cracks provided on a composite insulation layer. The cutting region may be connected to the crack dam region, and may at least include cutting grooves provided on the composite insulation layer. The cutting grooves are configured such that a cutting device cuts along the cutting grooves respectively after preparation of all film layers of the display substrate is completed.

In some examples, the bonding region B1 and the bezel region B2 may be provided with a first isolation dam and a second isolation dam, which may extend in a direction parallel to an edge of the display area to form a ring structure surrounding the display area AA, and the edge of the display area may be an edge of the display area close to the bonding region or the bezel region.

In some examples, as shown in FIG. 2, the display area AA may at least include a plurality of sub-pixels PX, a plurality of gate lines GL, and a plurality of data lines DL. A plurality of gate lines GL may extend along a first direction X, and a plurality of data lines DL may extend along a second direction Y. Orthographic projections of the plurality of gate lines GL on the base substrate and orthographic projections of the plurality of data lines DL on the base substrate intersect to form a plurality of sub-pixel regions, and one of the sub-pixels PX is disposed in each sub-pixel region. The plurality of data lines DL are electrically connected with the plurality of sub-pixels PX and the plurality of data lines DL may be configured to provide data signals to the plurality of sub-pixels PX. The plurality of data lines DL may extend to the bonding area B1. The plurality of gate lines GL are electrically connected with the plurality of sub-pixels PX and the plurality of gate lines GL may be configured to provide a gate control signal to the plurality of sub-pixels PX. In some examples, the gate control signal may include a scan signal and a light emitting control signal.

In some examples, as shown in FIG. 2, the first direction X may be an extension direction (row direction) of the gate lines GL in the display area AA, and the second direction Y may be an extension direction (column direction) of the data lines DL in the display area AA. The first direction X and the second direction Y may be perpendicular to each other.

In some examples, one pixel unit of the display area AA may include three sub-pixels which are a red sub-pixel, a green sub-pixel, and a blue sub-pixel respectively. However, this embodiment is not limited thereto. In some examples, one pixel unit may include four sub-pixels, and the four sub-pixels are a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged in parallel in a horizontal direction, in parallel in a vertical direction, or in a delta-shaped arrangement. When one pixel unit includes four sub-pixels, the four sub-pixels may be arranged in parallel in a horizontal direction, in parallel in a vertical direction, or in a shape forming a square. However, this embodiment is not limited thereto.

In some examples, one sub-pixel may include a pixel circuit and a light emitting element electrically connected with the pixel circuit. For example, the pixel circuit may be of a 3T1C (i.e., three transistors and one capacitor) structure, a 7T1C (i.e., seven transistors and one capacitor) structure, a 5T1C (i.e., five transistors and one capacitor) structure, an 8T1C (eight transistors and one capacitor) structure, or an 8T2C (eight transistors and two capacitors) structure, or the like.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, this embodiment is not limited thereto.

FIG. 3 is a schematic diagram of a partial sectional structure of a display area of a display substrate. FIG. 3 illustrates structures of three sub-pixels of the display substrate. In some example, as shown in FIG. 3, in a direction perpendicular to the display substrate, the display substrate may include: a base substrate 101, and a circuit structure layer 102, a light emitting structure layer 103, an encapsulation layer 104 and an encapsulation cover plate 200 that are sequentially disposed on the base substrate 101. In some possible implementations, the display substrate may include other film layers, such as a post spacer, a touch structure layer, which are not limited in the present disclosure herein.

In some examples, the base substrate 101 may be a rigid underlay substrate, e.g., a glass underlay substrate. However, this embodiment is not limited thereto. For example, the base substrate may be a flexible underlay substrate, e.g., prepared from an insulation material such as resin. In addition, the base substrate may in be a single-layer structure or a multi-layer structure. When the base substrate is a multi-layer structure, an inorganic material such as silicon nitride, silicon oxide, and silicon oxynitride may be arranged between a plurality of layers as a single layer or multiple layers.

In some examples, the circuit structure layer 102 of each sub-pixel may include a plurality of transistors and a storage capacitor which form a pixel circuit. Illustration is made in FIG. 3 by taking each sub-pixel including one transistor and one storage capacitor as an example. In some possible implementations, the circuit structure layer 102 of each sub-pixel may include: an active layer disposed on the base substrate 101; a first insulation layer 11 (or referred to as a first gate insulation layer) covering the active layer; a first gate metal layer (including, for example, a gate electrode of a transistor and a first capacitive electrode) disposed on the first insulation layer 11; a second insulation layer 12 (or referred to as a second gate insulation layer) covering the first gate metal layer; a second gate metal layer (e.g. including a second capacitive electrode) disposed on the second insulation layer 12; a third insulation layer 13 (or referred to as an interlayer insulation layer) covering the second gate metal layer, wherein the first insulation layer 11, the second insulation layer 12 and the third insulation layer 13 are provided with a plurality of first vias, and the plurality of vias expose the active layer; a first source-drain metal layer (including, for example, a source electrode and a drain electrode of a transistor) disposed on the third insulation layer 13, wherein the source electrode and the drain electrode may be connected to the active layer through first vias, respectively; and a first planarization 14 covering the structure, wherein the first planarization 14 is provided with a second via, the second via exposes the drain electrode. The active layer, the gate electrode, the source electrode, and the drain electrode may form the transistor 105, and the first capacitive electrode and the second capacitive electrode may form the storage capacitor 106.

In some examples, as shown in FIG. 3, the light emitting structure layer 103 may include an anode layer, a pixel definition layer, an organic emitting layer, and a cathode. The anode layer may include an anode of the light emitting element, the anode may be provided on the first planarization layer 14, and is electrically connected to the drain electrode of the transistor of the pixel circuit through a second via provided on the first planarization layer 14. A pixel definition layer is provided on the anode layer and the first planarization layer, and a pixel opening is provided on the pixel definition layer, and at least part of a surface of the anode is exposed by the pixel opening. The organic light emitting layer is at least partially provided in the pixel opening, and the organic light emitting layer is connected with the anode. The cathode is arranged on the organic light emitting layer, and the cathode is connected with the organic light emitting layer. The organic light emitting layer emits light of corresponding colors driven by the anode and cathode.

In some examples, as shown in FIG. 3, the encapsulation structure layer 104 may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is arranged between the first encapsulation layer and the third encapsulation layer, which may ensure that external moisture cannot enter the light light emitting structure layer 103.

In some examples, the organic light emitting layer may at least include a hole injection layer, a hole transport layer, a light emitting layer and a hole block layer which are stacked on the anode. In some examples, hole injection layers of all sub-pixels may be connected together as a common layer, hole transport layers of all sub-pixels may be connected together as a common layer, light emitting layers of adjacent sub-pixels may be slightly overlapped or isolated from each other, and hole block layers of adjacent sub-pixels may be connected together as a common layer. However, this embodiment is not limited thereto.

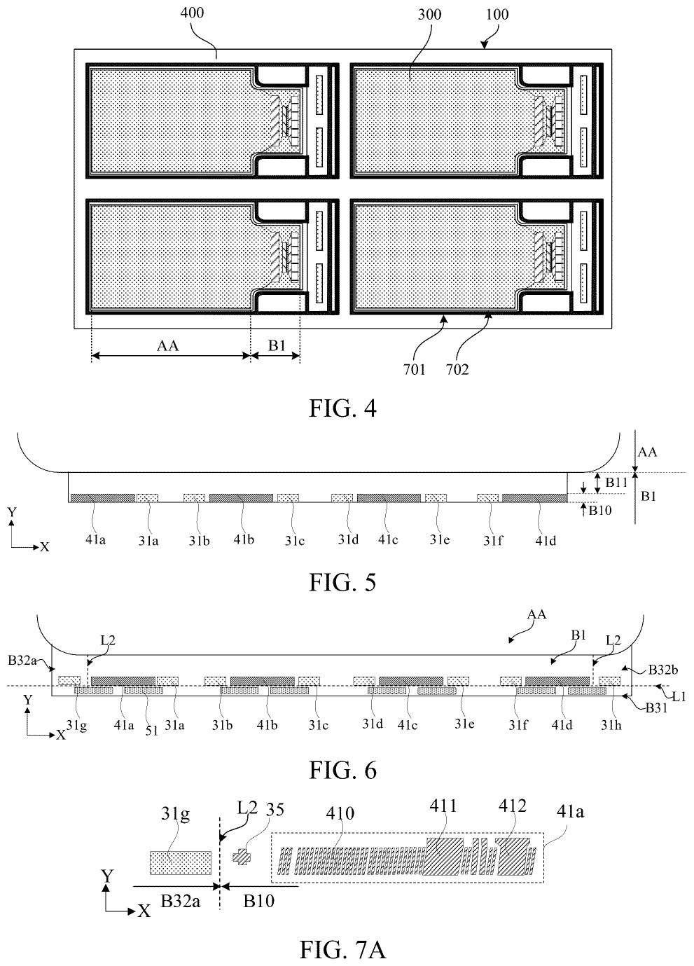

In some implementations, in a process of manufacturing the display substrate, a display mother plate may be manufactured first, and then the display mother plate may be cut, so that the display mother plate is divided into a plurality of display substrates, and a single display substrate may be used to form a single display apparatus. FIG. 4 is a schematic diagram showing an arrangement of a plurality of display substrates included in a display mother plate. As shown in FIG. 4, the display mother plate 100 may include a plurality of substrate regions 300 arranged periodically and regularly and cutting regions 400 located outside the substrate regions 300. A substrate area 300 includes at least a display area AA and a bonding area B1, and the bonding area B1 may include a bonding pin region on a side of the display area AA. A first cutting lane 701 and a second cutting lane 702 may be provided in the cutting region 400. After all film layers of the display mother plate are manufactured, the cutting equipment may perform rough cutting along the first cutting lane 701 and fine cutting along the second cutting lane 702 respectively.

In some implementations, a manufacturing process of a display substrate requires multiple tests, an important test of which is a Cell Test (CT for short) for light-on, also referred to as ET light-on test. ET light-on detection refers to that before the display substrate is not bonded to a circuit board, a detection signal is input to the display substrate to make its sub-pixels present colors, and a defect detection device checks whether each sub-pixel is in good condition to confirm whether there is a defect in the display substrate. Since there are situations, such as interface not stable, in a completed light emitting element, another important process for the display substrate is an aging procedure. The aging procedure (or aging stage) is a necessary process before the display apparatus is shipped. By lighting the light emitting element with a certain amount of current for a period of time, the interface instability can be aged away, brightness attenuation of the light emitting element can be reduced, and a service life of the light emitting element can be increased. Among them, the aging procedure needs implementing signal input through an aging pin group disposed on the display mother plate. However, with the improvement of resolution of display products and introduction of Flexible Multi-Layer On cell structure (FMLOC), the quantity of circuit boards bonded in the bonding area and required bonding pins are gradually increasing. As a result, space for placing aging pins in the bonding area is getting smaller and smaller, then how to place aging pins reasonably in the bonding area is a problem that needs to be solved.

This embodiment provides a display substrate, which includes a base substrate, a plurality of sub-pixels, a plurality of data lines, a plurality of test circuit groups, a plurality of aging pin groups, and a plurality of bonding pin groups. The base substrate includes a display area and a bonding area on one side of the display area. The plurality of sub-pixels are located in the display area. The plurality of data lines are located in the display area and the bonding area, and the plurality of data lines are electrically connected to the plurality of sub-pixels. The plurality of test circuit groups are arranged along a first direction, and the plurality of test circuit groups are electrically connected to the plurality of data lines. The plurality of aging pin groups and the plurality of bonding pin groups are located in the bonding area and on a side of the plurality of test circuit groups away from the display area. The plurality of bonding pin groups are arranged along the first direction, and at least one aging pin group is provided between adjacent bonding pin groups. Each bonding pin group is configured to be bonded and connected to at least one circuit board. Each test circuit group is configured to be connected to at least one aging pin group during the test stage.

In the display substrate according to this embodiment, by alternately setting aging pin groups among a plurality of bonding pin groups in the bonding area, aging pins can be arranged in the bonding area, thereby improving the situation that arrangement space of aging pins in the bonding area is insufficient.

In this embodiment, one aging pin group may include a plurality of aging pins arranged consecutively along the first direction, and one bonding pin group may include a plurality of bonding pins arranged consecutively along the first direction. The aging pins are configured as pins used during the aging stage. The bonding pins are configured as pins for bonding connections with circuit boards.

In some exemplary embodiments, the plurality of bonding pin groups may include n bonding pin groups, with n being a positive integer greater than or equal to 3, and the plurality of bonding pin groups sequentially include a first bonding pin group, a second bonding pin group . . . and an n-th bonding pin group along the first direction. An aging pin group included between a first bonding pin group and a second bonding pin group may include a plurality of first aging pins continuously arranged along the first direction for transmitting a gate drive control signal. An aging pin group included between the n-th bonding pin group and the (n-1)-th bonding pin group may include a plurality of first aging pins continuously arranged along the first direction for transmitting a gate drive control signal. In some examples, n can be 4. The first aging pins may be arranged between the first bonding pin group and the second bonding pin group and between a third bonding pin group and a fourth bonding pin group. This embodiment is not limited thereto. In some examples, the gate drive control signal may include a clock signal or the like provided to the gate drive circuit. In the manufacturing process of the display substrate, the EAC (EVEN After Cell, cutting after evaporation) cutting process has clear requirements for distances between the aging pins and rough cutting line (that is, the first cutting lane illustrated in FIG. 4). In this example, by setting the first aging pins between the first bonding pin group and the second bonding pin group, and between the n-th bonding pin group and the (n-1)-th bonding pin group, the situation that the arrangement space for aging pins is insufficient due to unable to be too close to the rough cutting lines of the EAC can be improved. Moreover, the arrangement of the first aging pins in this example can ensure that the first aging pins are connected to the gate drive circuits in the bezel area.

In some exemplary embodiments, two aging pin groups or one aging pin group may be arranged between two adjacent bonding pin groups. For example, by combining a plurality of aging pins between adjacent bonding pin groups into two groups or one group, space occupied by the arrangement of aging pins can be saved, so that the situation of insufficient arrangement space for aging pins in the bonding area can be improved.

In some exemplary embodiments, each of the plurality of aging pin groups may include a plurality of second aging pins continuously arranged along the first direction for transmitting a DC signal. In some examples, the DC signal may include at least one of a high voltage signal and a low voltage signal provided to a gate drive circuit, an initial signal provided to a pixel circuit, a test control signal and a test data signal provided to a test circuit. This embodiment is not limited thereto.

In some exemplary embodiments, at least one of the plurality of aging pin groups may include a plurality of first aging pins continuously arranged along the first direction for transmitting a gate drive control signal and a plurality of second aging pins continuously arranged along the first direction for transmitting a DC signal. Here, the plurality of second aging pins in the aging pin group may be located on a side of the plurality of first aging pins close to an edge of the display substrate. In this example, a plurality of first aging pins and a plurality of second aging pins may be arranged in at least one aging pin group, the space occupied for arranging the aging pins can be saved by combining the aging pins, and arrangement positions of the first aging pins and the second aging pins are set to be conducive to optimizing arrangement of connection wiring between the first aging pins and the second aging pins, and other circuits and pins.

In some exemplary embodiments, the first aging pin of at least one of the plurality of aging pin groups may be configured to be electrically connected to first aging pins transmitting a same signal in remaining aging pin groups during the test stage. In this way, consistency between signals transmitted by the first aging pins can be ensured.

In some exemplary embodiments, second aging pins transmitting a same signal among a plurality of aging pin groups may be configured to be electrically connected during the test stage. In this way, consistency between signals transmitted by the second aging pins can be ensured.

In some exemplary embodiments, a plurality of test circuit groups may be connected through test circuit connection lines. In this way, consistency between signals received by the test circuit groups can be ensured.

In some exemplary embodiments, at least one of the plurality of test circuit groups is configured to be connected to two aging pin groups during the test stage, and the two aging pin groups are located on two sides of the at least one test circuit group. In this example, the test circuit groups are connected with the aging pin groups, so that consistency between signals received by the test circuit groups can be ensured.

In some exemplary embodiments, pins transmitting a same signal in aging pin groups which are electrically connected to different test circuit groups and arranged adjacent to each other are configured to be electrically connected during the test stage. Pins transmitting a same signal in aging pin groups which are electrically connected to a same test circuit group and arranged adjacent to each other are configured to be electrically connected to each other during the test stage. In this example, the consistency of signal transmission in the test stage can be ensure by implementing the electrical connection between the pins transmitting the same signal in the aging pin group during the test stage.

In some exemplary embodiments, the plurality of aging pin groups may be arranged along the first direction, and the plurality of aging pin groups and the plurality of bonding pin groups may be arranged side by side in the first direction. In this example, by arranging the aging pin groups and the bonding pin groups side by side, space occupied by the aging pin groups can be saved.

In some exemplary embodiments, each of the plurality of bonding pin groups may include a plurality of access pins, at least one first power supply pin, and at least one second power supply pin arranged along the first direction. A first power supply pin and a second power supply pin in each bonding pin group are configured to be used as aging pins during the aging stage, and each bonding pin group is configured to be bonded to at least one circuit board after the aging stage. In some examples, for one display mother plate, a cutting process may be performed first along an EAC cutting line to cut the display mother plate into a plurality of intermediate substrates (e.g., one intermediate substrate may include a substrate region, a first cutting region, and a second cutting region), and then light-on detection and aging stages are performed on each intermediate substrate. After the detection and aging stages are completed, cutting may be performed along a Module (MDL, Module) cutting line of the intermediate substrate, and then a circuit board is bonded to the intermediate substrate. A display substrate can be obtained by edge cutting an intermediate substrate on which the bonding of the circuit board is completed.

In some implementations, connection positions of the aging pins provided on the display mother plate and the wirings of the display substrate are interconnected by vias at the module cutting line by using two layers of different materials. For example, the aging pins may be located in a source-drain metal layer (e.g., the first source-drain metal layer), and the source-drain metal layer may have a small resistance (e.g., a stacked structure of titanium, aluminum, and titanium). The wirings of the display substrate at the module cutting line may be located in a gate metal layer (e.g., a first gate metal layer or a second gate metal layer), and the gate metal layer may have a high resistance (e.g., a metal material, molybdenum, is used). During the aging stage, a detection current will pass through the source-drain metal layer and the gate metal layer. Since test currents of a first power supply voltage (VDD) and a second power supply voltage (VSS) for a large-sized display substrate are relatively large, when a large current flows through the gate metal layer with large resistance, due to the high resistance, according to Q=I2Rt, high heat will be generated at the gate metal layer of the display substrate, thereby causing a burning loss on the display substrate. In this example, by commonly using the first power supply pin and the second power supply pin in the bonding pin group as aging pins, the current flowing through the position of the module cutting line can be reduced, thereby reducing the current flowing through the gate metal layer, and improving the burning loss caused by the display substrate. Moreover, there is no need to separately set the aging pins for transmitting the first power supply voltage and the second power supply voltage, and the space occupied by the aging pins can be reduced.

Solutions of the embodiments will be described below through some examples. In the following example, only the bonding area of the display substrate and a cutting position on the display mother plate near the bonding area of the display substrate are described.

FIG. 5 is a schematic view of a bonding area of a display substrate according to at least one embodiment of the present disclosure. In some examples, as shown in FIG. 5, the bonding area B1 may include a sub-bezel region B11 and a bonding pin region B10 along a direction away from the display area AA. The bonding pin region B10 may be located on a side of the sub-bezel region B11 away from the display area AA.

In some examples, taking the display substrate being a flexible substrate as an example, the sub-bezel region B11 may include a first fan-out region, a bending region, a second fan-out region, a first circuit region, a third fan-out region, and a driver chip region sequentially disposed along the direction away from the display area AA. The first fan-out region may be connected to the display area, and includes at least a first power supply line, a second power supply line and a plurality of data lines. The plurality of data lines are configured as the data lines of the display area extending in a fan-out wiring manner. A first power supply line of the first fan-out region may be configured to be connected to a high-level power supply line of the display area, and a second power supply line may be configured to be connected to a low-level power supply line of the bezel region. The bending region may be connected to the second fan-out region and may include a composite insulation layer provided with a groove, and the groove is configured to allow the bonding area 200 to be bent to a back of the display area 100. The second fan-out region may include a plurality of fan-out wirings. The first circuit region may include at least an electrostatic circuit, which may be configured to prevent electrostatic damages to the display substrate by eliminating electrostatic. The third fan-out region may include a plurality of fan-out wirings. The driver chip region may be provided with a driver chip (IC, Integrated Circuit), the driver chip may be electrically connected to the data line of the display area through a fan-out wiring, and the driver chip may be configured to generate a driving signal required for driving sub-pixels, and provide the driving signal to the data lines of the display area. For example, the drive signal may be a data signal that drives the sub-pixels to emit light. In another example, taking the display substrate being a rigid substrate as an example, the sub-bezel region B11 may include a second circuit region and a fan-out wiring region arranged in sequence along the direction away from the display area AA. The second circuit region may include a multiplexing circuit and an electrostatic discharge circuit. The multiplexing circuit may be configured to enable one signal source to provide data signals for a plurality of data lines. The fan-out wiring area may include a plurality of fan-out wirings extending to the bonding area. However, the structure of the sub-bezel region B11 is not limited in this embodiment.

In some examples, as shown in FIG. 5, the bonding pin region B10 may include a plurality of aging pin groups (e.g., six aging pin groups 31a to 31f) and a plurality of bonding pin groups (e.g., four bonding pin groups 41a to 41d). The four bonding pin groups 41a to 41d are sequentially disposed along the first direction X, and the six aging pin groups 31a to 31f are sequentially disposed along the first direction X. A plurality of aging pin groups and a plurality of bonding pin groups may be alternately arranged along the first direction X. For example, two aging pin groups may be provided between two adjacent bonding pin groups. For example, aging pin groups 31a and 31b may be provided between bonding pin groups 41a and 41b, aging pin groups 31c and 31d may be provided between bonding pin groups 41b and 41c, and aging pin groups 31e and 31f may be provided between bonding pin groups 41c and 41d. Each aging pin group may include a plurality of aging pins sequentially arranged along the first direction X, and each bonding pin group may include a plurality of bonding pins sequentially arranged along the first direction X. Each bonding pin group may be configured to be bonded and connected to a at least one circuit board (e.g., Flexible Printed Circuit, FPC) corresponding thereto. Here, the aging pin groups may be configured to be used during the aging stage or the test stage, and after the aging stage and the test stage are completed, and the bonding pin group is bonded to the circuit board, the aging pin group may be retained in the bonding pin region B10 as invalid pins.

FIG. 6 is a partial schematic view of a display mother plate according to at least one embodiment of the present disclosure. In some examples, as shown in FIG. 6, the display mother plate may include at least one substrate region. A display substrate includes a display area AA and a bonding area B1 on one side of the display area AA. A cutting region may be located on an outer side of the substrate region. For example, the cutting region may include a first cutting region B31 located on a side of the bonding area B1 away from the display area AA, and second cutting regions B32a and B32b located on opposite sides of the bonding pin region of the bonding area B1 in the first direction X. This example omits cutting regions schematically on remaining sides of the substrate region.

In some examples, for one display mother plate, a cutting process may be first performed along an EAC cutting line to cut the display mother plate into a plurality of intermediate substrates (e.g., one intermediate substrate may include a substrate region, a first cutting region, and a second cutting region), and then light-on detection and aging procedures are performed on each intermediate substrate. After the light-on detection and aging procedures are completed, cutting may be performed along a Module (MDL) cutting line of the intermediate substrate, and then a circuit board is bonded to the intermediate substrate. A display substrate is obtained by edge cutting an intermediate substrate on which the bonding of the circuit board is completed. FIG. 6 is a partial schematic view of a display mother plate from which the display substrate shown in FIG. 5 is obtained. The display substrate shown in FIG. 5 can be obtained by cutting the display mother plate shown in FIG. 6. The cutting line L1 in FIG. 6 is the module cutting line described above. After the light-on detection and aging procedures are completed, the first cutting region B31 can be cut off according to the cutting line L1. After bonding of the circuit board is completed, the second cutting circuits B32a and B32b can be cut off according to the cutting lines L2.

In some examples, as shown in FIG. 6, the first cutting region B31 is provided with a plurality of test pin groups 51. Each test pin group may include a plurality of test pins arranged along the first direction X. The test pins are configured as pins for signal transmission during a light-on test stage. The second cutting region B32a may be provided with an aging pin group 31g, and the second cutting region B32b may be provided with an aging pin group 31h. The aging pin groups 31g and 31h may be arranged side by side in the first direction X with a plurality of aging pin groups and a plurality of bonding pin groups in the bonding area.

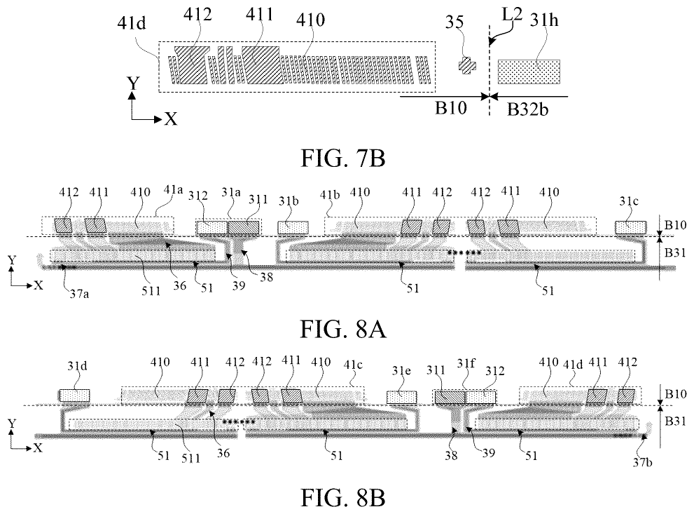

FIG. 7A is a schematic diagram illustrating local distribution of the aging pin group 31g and the bonding pin group 41a in FIG. 6. FIG. 7B is a schematic diagram illustrating local distribution of the aging pin group 31h and the bonded pin group 41d in FIG. 6.

In some examples, taking the aging pin group 31g and the bonding pin group 41a as an example, as shown in FIG. 7A, a alignment mark 35 may be provided between the aging pin group 31g and the bonding pin group 41a. An orthographic projection of the alignment mark 35 on base the substrate may be cross-shaped. The aging pin group 31g may be located on a side of the cutting line L2 away from the bonding pin group 41a. The bonding pin group 41a may include a plurality of access pins 410, a first power supply pin 411, and a second power supply pin 412. The first power supply pin 411 may be configured to transmit a low-level power supply signal VSS, and the second power supply pin 412 may be configured to transmit a high-level power supply signal VDD. The first power supply pin 411 and the second power supply pin 412 may be interspersed between the plurality of access pins 410. In some examples, the plurality of aging pins in the aging pin group 31a, the plurality of pins in the bonding pin group 41a, and the alignment mark 35 may be arranged in a same layer, for example, may all be located in the first source drain metal layer. In some other examples, the plurality of aging pins and bonding pins may be in a double-layer stacked structure, for example, may be in a stacked structure with a first gate metal layer and a first source-drain metal layer, or a stacked structure with a second gate metal layer and a first source-drain metal layer. The pins in the aging pin group and the bonding pin group in this example may extend substantially in the second direction Y and be arranged along the first direction X.

In some examples, as shown in FIG. 7A, the first power supply pin 411 and the second power supply pin 412 in the bonding pin group 41a may be configured to be used as aging pins during the aging stage to transmit a power supply signal during the aging stage, which reduces the current flowing through the position of the module cutting line during the aging stage, and improve the burning loss caused to the display substrate. Lengths of the first power supply pin 411 and the second power supply pin 412 in the first direction X may be greater than lengths of other pins in the first direction X, i.e., widths of the first power supply pin 411 and the second power supply pin 412 may be greater than widths of other pins. Length of a plurality of pins in the bonding pin group 41a may be substantially the same in the second direction Y. Or, lengths of the first power supply pin 411 and the second power supply pin 412 in the second direction Y may be greater than lengths of other pins in the second direction Y. However, this embodiment is not limited thereto.

A positional relationship between the bonding pin group 41d and the aging pin group 31h in FIG. 7B is as illustrated in FIG. 7A, thus will not be described here in detail.

FIGS. 8A and 8B are partial schematic views of the bonding pin region and the first cutting region in FIG. 6. In some examples, as shown in FIGS. 8A and 8B, the first cutting region B31 includes a plurality of test pin groups 51 arranged along the first direction X. Each test pin group 51 in the first cutting region B31 may include a plurality of test pins 511 arranged consecutively along the first direction X. The plurality of test pins 511 may extend substantially in the second direction Y. The plurality of test pins 511 may be electrically connected to a plurality of pins in a bonding pin group in the bonding pin region B10 via a plurality of first connection lines 36, so as to be configured to provide a test signal. For example, one test pin 511 may be electrically connected to one bonding pin via one first connection line 36. A plurality of first connection lines 36 may be located in the first cutting region B31 and on a side of the test pin groups 51 adjacent to the bonding pin region B10. The first connection lines 36 may, for example, extend substantially in the second direction Y.

In some examples, as shown in FIG. 8A, the aging pin group 31a included between the first bonding pin group 41a and the second bonding pin group 41b may include a first aging pin group 311 and a second aging pin group 312. The first aging pin group 311 may include a plurality of first aging pins continuously arranged along the first direction X for transmitting a gate drive control signal. The second aging pin group 312 may include a plurality of second aging pins continuously arranged along the first direction X for transmitting a DC signal. The second aging pin group 312 may be located on a side of the first aging pin group 311 close to a left edge of the display substrate. In some examples, the second aging pin group 312 may include eight second aging pins, and the first aging pin group 311 may include nine first aging pins. For example, the second aging pin group 312 may include three test data pins, one test control pin, two power supply pins, and two initial signal pins arranged sequentially along the first direction X. The three test data pins may be configured to provide a test data signal to the test circuit during the test stage. The test control pin may be configured to provide a test control signal to a test circuit during the test stage. The two power supply pins may be configured to provide a high voltage signal and a low voltage signal to a gate drive circuit during the test stage. The two initial signal pins may be configured to provide an initial signal to a pixel circuit during the test stage. However, this embodiment is not limited thereto. For example, the second aging pin group may include a power supply pin that supplies a power supply signal to the gate drive circuit.

In some examples, as shown in FIG. 8B, the aging pin group 31f included between the third bonding pin group 41c and the fourth bonding pin group 41d may include a first aging pin group 311 and a second aging pin group 312. Here, the second aging pin group 312 may be located on a side of the first aging pin group 311 close to a right edge of the display substrate. The pins in the first aging pin group 311 and the second aging pin group 312 can be described with reference to the foregoing embodiment, thus will not be described here in detail.

In some examples, as shown in FIG. 8A, first aging pins in the first aging pin group 311 in the aging pin group 31a may be electrically connected to a gate drive circuit provided in the bezel area (e.g., the left bezel) through a first adapter line 37a. First aging pins in the first aging pin group 311 in the aging pin group 31f may be electrically connected to agate drive circuit provided in the bezel region (e.g., the right bezel) through a first adapter line 37b. The first adapter lines 37a and 37b may include at least a line segment extending in the first direction X. The line segment extending in the first direction X may be located on a side of the test pin group 51 away from the bonding pin region B10, and the line segment extending in the second direction Y may be located on a side of the test pin group 51 close to an edge of the display substrate in the first direction X. However, this embodiment is not limited thereto.

In some examples, as shown in FIGS. 8A and 8B, the aging pin groups 31b, 31c, 31d, and 31e may respectively include a plurality of second aging pins arranged consecutively along the first direction X. As shown in FIGS. 7A and 7B, the aging pin groups 31g and 31h may respectively include a plurality of second aging pins arranged consecutively along the first direction X. In some examples, the quantity of second aging pins in each aging pin group may be the same, for example, may be 8, and the quantity of first aging pins in aging pin groups 31a or 31f may be 9. This embodiment is not limited thereto. In this example, the first aging pins may be arranged only between the first bonding pin group 41a and the second bonding pin group 41b, and between the third bonding pin group 41c and the fourth bonding pin group 41d.

In some examples, as shown in FIGS. 8A and 8B, a first aging pin in the first aging pin group 311 in the aging pin group 31a may be electrically connected to a first aging pin in the first aging pin group 311 in the aging pin group 31f transmitting a same signal through a second connection line 38. The second connection line 38 may include at least a line segment extending in the first direction X and a line segment extending in the second direction Y. The line segment extending in the first direction X may be located on a side of the test pin groups 51 away from the bonding pin region B10. In some examples, the second connection line 38 may be electrically connected with the first adapter lines 37a and 37b to ensure consistency of signal transmission.

In some examples, as shown in FIGS. 8A and 8B, the second aging pins in the second aging pin group 312 in the aging pin group 31a may be electrically connected to second aging pins in remaining aging pin groups transmitting a same signal through a third connection line 39. The third connection line 39 may include at least a line segment extending in the first direction X and a line segment extending in the second direction Y. The line segment extending in the first direction X may be located on a side of the test pin groups 51 away from the bonding pin region B10. In this example, by electrically connecting the second aging pins transmitting the same signal, the consistency of signal transmission can be ensured.

In some examples, the first adapter lines 37a and 37b, the second connection line 38 and the third connection line 39 may be located in a same conductive layer, such as the first source-drain metal layer. When the first adapter line 37a and 37b intersect the second connection line 38 and the third connection line 39, the first adapter line 37a and 37b can bypass the second connection line 38 and the third connection line 39 by using jumpers of different conductive layers (e.g., located in the first gate metal layer or the second gate metal layer). Or, the second connection line 38 and the third connection line 39 may bypass the first adapter lines 37a and 37b using jumpers located in different conductive layers. This embodiment is not limited thereto.

The following is an example of the display substrate being a flexible display substrate.

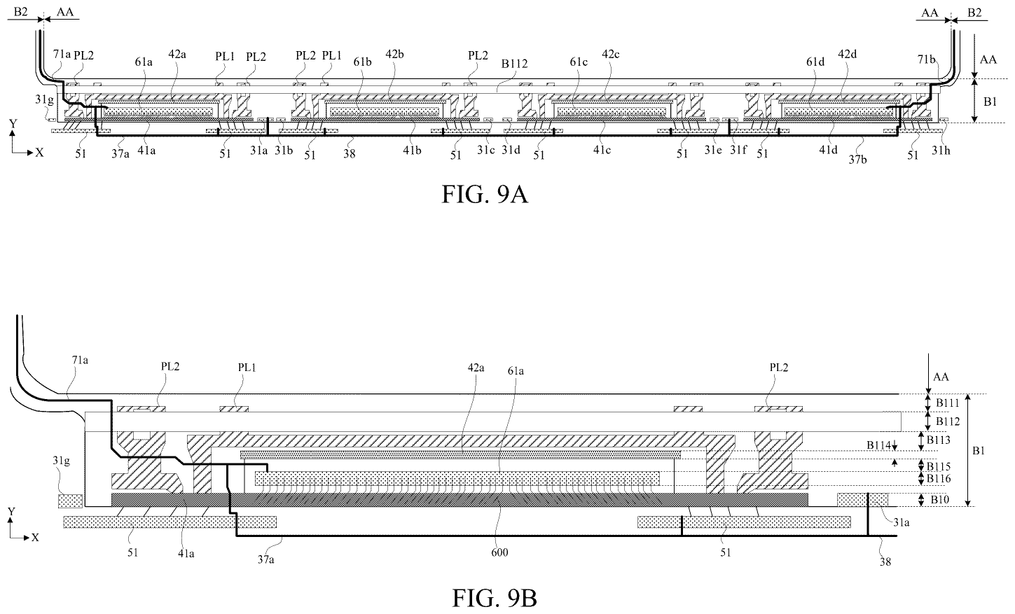

FIG. 9A is a schematic diagram of a bonding area of a display substrate according to at least one embodiment of the present disclosure. FIG. 9B is a partial schematic view of a bonding area of the display substrate in FIG. 9A. FIG. 9A and FIG. 9B illustrate the bonding area of the display substrate, a plurality of test pin groups 51 disposed on a side of the bonding area away from the display area, and aging pin groups (e.g., aging pin groups 31g and 31h) located at a periphery of the bonding area B1 in the first direction X.

In some examples, as shown in FIGS. 9A and 9B, the bonding area B1 of the display substrate may include a first fan-out region B111, a bending region B112, a second fan-out region B113, a first circuit region B114, a third fan-out region B115, a driver chip region B116, and a bonding pin region B10 sequentially disposed along a direction away from the display area AA. The first fan-out region B111 may be connected to the display area AA. The bending region B112 is connected between the first fan-out region B111 and the second fan-out region B112 and may be configured such that the bonding area B1 is bent to the back of the display area AA. The first circuit region B114 may include at least a plurality of test circuit groups (including, for example, test circuit groups 42a, 42b, 42c, and 42_{d}). A plurality of test circuit groups may be arranged side by side along the first direction X. Each test circuit group may include a plurality of test circuits, the test circuits may be configured to be electrically connected to a plurality of data lines of the display area to provide test data signals to the plurality of data lines of the display area. The driver chip region B116 includes a plurality of driver chip pin groups (including, for example, driver chip pin groups 61a, 61b, 61c, and 61d). The plurality of driver chip pin groups may be electrically connected to a plurality of data lines and are configured to be bonded to at least one driver chip. For example, each driver chip pin group may be configured to be bonded to one driver chip. Fan-out wirings in the first fan-out region B111, the second fan-out region B113, and the third fan-out region B115 are omitted in FIGS. 9A and 9B. FIGS. 9A and 9B illustrate several connection lines between a test circuit group and a bonding pin group, and connection lines between the bonding pin group and a test pin group. Quantities of these connection lines are limited not in this embodiment.

In some examples, as shown in FIGS. 9A and 9B, the bonding area B1 may include a plurality of first power supply lines PL1 and a plurality of second power supply lines PL2. A bonding pin group (e.g., a bonding pin group 41a) in the bonding pin region B10 may be electrically connected to two second power supply lines PL2 and one first power supply line PL1, and the first power supply line PL1 may be located between the two second power supply lines PL2 in the first direction X. The first power supply line PL1 may be electrically connected to a second power supply pin of the bonding pin group in the bonding pin region B10, and the second power supply line PL2 may be electrically connected to a first power supply pin in the bonding pin group. In some examples, the first power supply line PL1 and the second power supply line PL2 may be single-layer wirings, for example, may be located in the first source-drain metal layer or the second source-drain metal layer. Or, the first power supply line PL1 and the second power supply line PL2 may be double-layered wirings, for example, may be in a stacked wiring structure of the first source-drain metal layer and the second source-drain metal layer. This embodiment is not limited thereto.

In some examples, as shown in FIGS. 9A and 9B, a plurality of driver chip pin groups in the driver chip region B116 may be arranged side by side along the first direction X. The quantity of driver chip pin groups in the driver chip region B116 may be the same as the quantity of bonding pin groups in the bonding pin region B10. A plurality of driver chip pin groups and a plurality of bonding pin groups may be connected one-to-one correspondingly. Pins in a driver chip pin group may be electrically connected to pins in the corresponding bonding pin group through pin connection lines 600. The pin connection lines 600 may extend substantially in the second direction Y and may be arranged sequentially along the first direction X. For example, a driver chip pin group 61a is correspondingly connected to a bonding pin group 41a, a driver chip pin group 61b is correspondingly connected to a bonding pin group 41b, a driver chip pin group 61c is correspondingly connected to a bonding pin group 41c, and a driver chip pin group 61d is correspondingly connected to a bonding pin group 41d. This embodiment is not limited thereto.

In some examples, as shown in FIGS. 9A and 9B, a gate drive circuit located in the left bezel of the bezel region B2 may be electrically connected to a first signal transmission line 71a, and the first signal transmission line 71a may extend to the bonding area B1 via a lower left corner. The first signal transmission line 71a passes through the first fan-out region B111, the bending region B112, the second fan-out region B113, and the third fan-out region B115 in the bonding area B1, and may be electrically connected to a pin in a driver chip pin group (e.g., the driver chip pin group 61a) located closest to the left edge of the display substrate in the driver chip region B116. A gate drive circuit located in the right bezel of the bezel region B2 is electrically connected to a first signal transmission line 71b, and the first signal transmission line 71b may extend to the bonding area B1 via a lower right corner. The first signal transmission line 71b passes through the first fan-out region B111, the bending region B112, the second fan-out region B113, and the third fan-out region B115 in the bonding area B1, and may be electrically connected to a pin in a driver chip pin group (e.g., the driver chip pin group 61d) located closest to the right edge of the display substrate in the driver chip region B116. In other words, the first signal transmission line 71a may be electrically connected to a pin in the first driver chip pin group 61a, and the first signal transmission line 71b may be electrically connected to a pin in the last driver chip pin group 61d.

In some examples, as shown in FIGS. 9A and 9B, the first signal transmission line 71a may be electrically connected to the first adapter line 37a, and the first signal transmission line 71b may be electrically connected to the first adapter line 37b. A connection position between the first signal transmission line 71a and the first adapter line 37a may be located on a side of the first power supply line PL1 close to the driver chip pin group 61a. A connection position between the first signal transmission line 71b and the first adapter line 37b may be located on a side of the first power supply line PL1 close to the driver chip pin group 61d. The first adapter line 37a may be electrically connected to a first aging pin in the aging pin group 31a, and may also be electrically connected to a test pin in a test pin group 51 on a side of the aging pin group 31a close to the left edge of the display substrate that transmits a same signal. The first adapter line 37b may be electrically connected to a first aging pin in the aging pin group 31f, and may also be electrically connected to a test pin in a test pin group 51 on a side of the aging pin group 31f close to the right edge of the display substrate that transmits a same signal. The first adapter line 37a and the second adapter line 37b may be electrically connected through a second connection line 38. The second connection line 38 may also be electrically connected to test pins transmitting a same signal in the plurality of test pin groups 51. In this example, the first aging pin can be electrically connected to the gate drive circuit by electrically connecting the first adapter line 37a to the first signal transmission line 71a, and electrically connecting the first adapter line 37b to the first signal transmission line 71b. In the test stage, the first signal transmission lines 71a and 71b are communicated through the first adapter lines 37a and 37b and the second connection line 38, so that consistency of signal transmission can be ensured. The signal transmitted to the first aging pin may include, for example, a clock signal provided to the gate drive circuit.

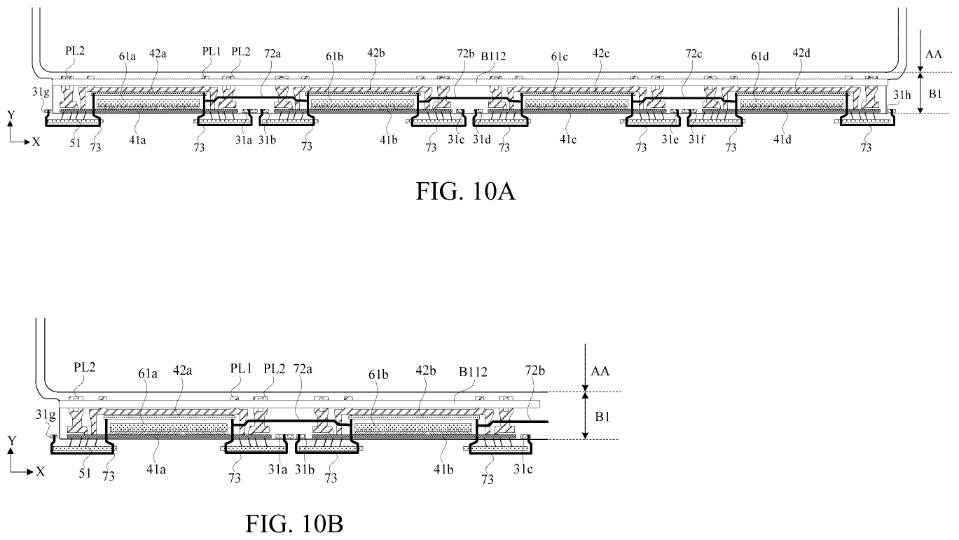

FIG. 10A is a schematic diagram of a bonding area of a display substrate according to at least one embodiment of the present disclosure. FIG. 10B is a partial schematic view of a bonding area of the display substrate in FIG. 10A. A connection relationship between an aging pin group and the test circuit group is illustrated in FIGS. 10A and 10B.

In some examples, as shown in FIGS. 10A and 10B, the first circuit region may include a plurality of test circuit groups (including, for example, test circuit groups 42a, 42b, 42c, and 42d) sequentially disposed along the first direction X. The quantity of test circuit groups may be the same as the quantity of driver chip pin groups. Each test circuit group may be located on a side of the corresponding driver chip pin group close to the display area AA. A plurality of test circuit groups may be electrically connected to each other by test circuit connection lines. For example, adjacent test circuit groups may be electrically connected by a test circuit connection line. In this example, the test circuit groups 42a and 42b may be electrically connected by a test circuit connection line 72a, the test circuit groups 42b and 42c may be electrically connected by a test circuit connection line 72b, and the test circuit groups 42c and 42d may be electrically connected by a test circuit connection line 72c. The test circuit connection lines 72a, 72b, and 72c may extend, for example, in the first direction X. The test circuit connection lines 72a, 72b, and 72c may be located on a side of the bonding pin region close to the display area.

In some examples, as shown in FIGS. 10A and 10B, during the test stage, the test circuit group 42a may be configured to be connected to two aging pin groups 31a and 31g, and the aging pin groups 31a and 31g may be located on two side of the test circuit group 42a. During the test stage, the test circuit group 42b may be configured to be connected to two aging pin groups 31b and 31c, and the aging pin groups 31b and 31c may be located on two side of the test circuit group 42b. During the test stage, the test circuit group 42c may be configured to be connected to two aging pin groups 31d and 31e, and the aging pin groups 31d and 31e may be located on two side of the test circuit group 42c. During the test stage, the test circuit group 42d may be configured to be connected to two aging pin groups 31f and 31h, and the aging pin groups 31f and 31h may be located on two side of the test circuit group 42d.

In some examples, as shown in FIGS. 10A and 10B, the test circuit group and adjacent aging pin groups may be electrically connected by first test connection lines 73. For example, the test circuit group 42a may be electrically connected to an aging pin (e.g., a second aging pin) in the aging pin group 31a through a first test connection line 73, and the test circuit group 42a may be electrically connected to an aging pin in the aging pin group 31g through a first test connection line 73. After one end of the first test connection line 73 is electrically connected to a test circuit group, it may extend substantially in the second direction Y to be electrically connected to a test pin group 51 corresponding to the test circuit group, and the first test connection line 73 may be electrically connected to an aging pin group after extending in the first direction X on a side of the test pin group 51 away from the display area AA and bypassing the test pin group 51. Pins transmitting the same signal in the test pin group 51 and the aging pin group can be electrically connected to each other and electrically connected to the test circuit group by using the first test connection lines 73. Two ends of one test circuit connection line may be electrically connected to two different first test connection lines 73. Rest of the structure of the display substrate according to this embodiment may be referred to descriptions of the aforementioned embodiments, and will not be repeated here.

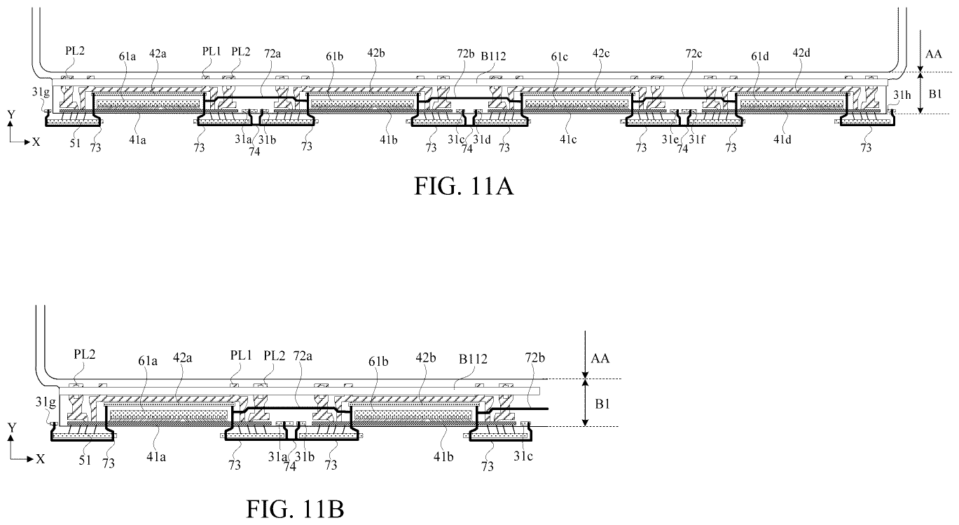

FIG. 11A is a schematic diagram of a bonding area of a display substrate according to at least one embodiment of the present disclosure. FIG. 11B is a partial schematic view of a bonding area of the display substrate in FIG. 11A. FIGS. 11A and 11B illustrate a connection relationship between an aging pin group and a test circuit group, and a connection relationship between aging pin groups.

In some examples, as shown in FIGS. 11A and 11B, a first test connection line 73 electrically connected to the test circuit group 42a and a first test connection line 73 electrically connected to the test circuit group 42b may be electrically connected through a second test connection line 74. The first test connection line 73 electrically connected to the test circuit group 42b and a first test connection line 73 electrically connected to the test circuit group 42c may be electrically connected through a second test connection line 74. The first test connection line 73 electrically connected to the test circuit group 42c and a first test connection line 73 electrically connected to the test circuit group 42d may be electrically connected through a second test connection line 74. In this example, the first test connection lines that are respectively electrically connected to adjacent test circuit groups may be electrically connected through the second test connection lines. The second test connection line 74 may extend along the first direction X. The second test connection line 74 may be electrically connected to a segment extending in the first direction X of the first test connection line 73. For example, the second test connection line 74 and the electrically connected first test connection line 73 may be formed into an integrated structure.

In this example, aging pins that transmit the same test signal in aging pin groups that are electrically connected to different test circuit groups and arranged adjacent to each other can be electrically connected through the first test connection line and the second test connection line, so as to achieve uniform transmission of signals. Rest of the structure of the display substrate according to this embodiment may be referred to descriptions of the aforementioned embodiments, and will not be repeated here.

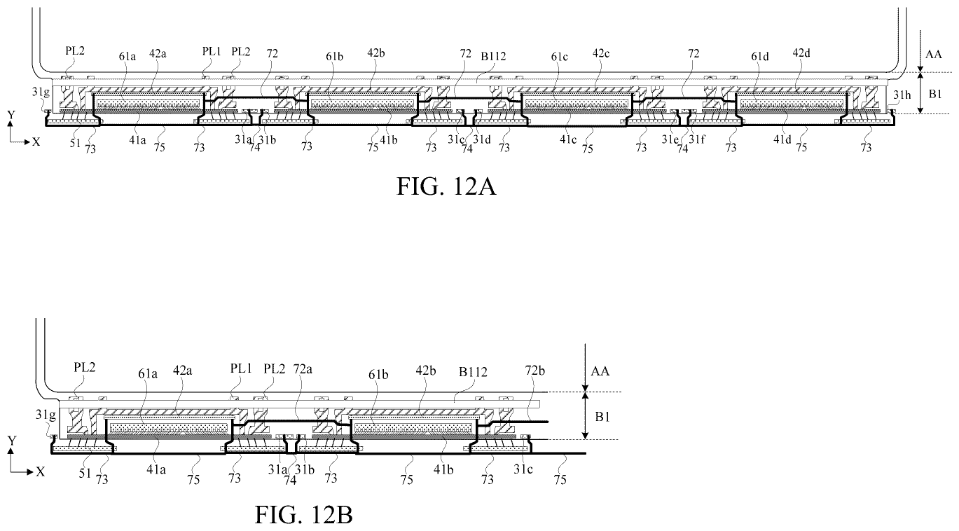

FIG. 12A is a schematic diagram of a bonding area of a display substrate according to at least one embodiment of the present disclosure. FIG. 12B is a partial schematic view of a bonding area of the display substrate in FIG. 12A. FIGS. 12A and 12B illustrate a connection relationship between an aging pin group and a test circuit group and another connection relationship between aging pin groups.

In some examples, as shown in FIGS. 12A and 12B, first test connection lines 73 electrically connected to two aging pin groups electrically connected to a same test circuit group and adjacent to each other may be electrically connected by a third test connection line 75. For example, a first test connection line 73 electrically connected to the aging pin group 31g and a first test connection line 73 electrically connected to the aging pin group 31a may be electrically connected through a third test connection line 75. A first test connection line 73 electrically connected to the aging pin group 31b and a first test connection line 73 electrically connected to the aging pin group 31c may be electrically connected through a third test connection line 75. A first test connection line 73 electrically connected to the aging pin group 31d and a first test connection line 73 electrically connected to the aging pin group 31e may be electrically connected through a third test connection line 75. A first test connection line 73 electrically connected to the aging pin group 31f and a first test connection line 73 electrically connected to the aging pin group 31h may be electrically connected through a third test connection line 75. A third test connection line 75 may be electrically connected to a segment extending in the first direction X of a first test connection line 73. For example, the third test connection line 75 and the electrically connected first test connection line 73 may be formed into an integrated structure.

In this example, aging pins that are electrically connected to different test circuit groups and transmit a same test signal in adjacent aging pin groups may be electrically connected through a first test connection line and a second test connection line. Aging pins that are electrically connected with a same test circuit group and transmit a same test signal in adjacent aging pin groups can be electrically connected through a first test connection line and a third test connection line, so as to achieve uniform transmission of signals. In this example, aging pins located in different aging pin groups and transmitting the same signal to the test circuit group can be electrically connected through the first test connection line, the second test connection line and the third test connection line, so as to ensure the uniformity of signal transmission. Rest of the structure of the display substrate according to this embodiment may be referred to descriptions of the aforementioned embodiments, and will not be repeated here.

In some examples, third connection lines 39 connected to aging pins electrically connected to the test circuit group may include a first test connection line and a second test connection line, or may include a first test connection line and a third test connection line, or may include a first test connection line, a second test connection line, and a third test connection line. This embodiment is not limited thereto.

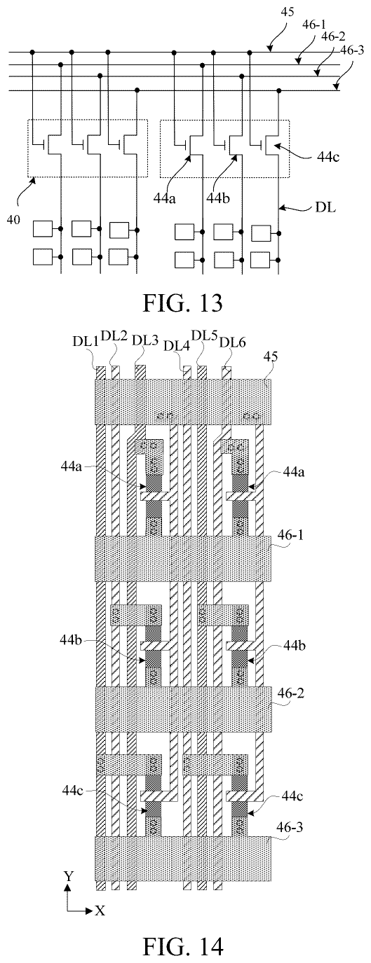

FIG. 13 is an equivalent circuit diagram of a test circuit according to at least one embodiment of the present disclosure. In some examples, the first circuit region of the bonding area includes a plurality of test circuit groups, and each of the test circuit groups may include a plurality of test circuits 40. A test circuit 40 may include a plurality of test transistors (including, for example, a first test transistor 44a, a second test transistor 44b, and a third test transistor 44c). As shown in FIG. 13, a gate of the first test transistor 44a, a gate of the second test transistor 44b, and a gate of the third test transistor 44c are all connected to a same test control signal line 45. A first electrode of the first test transistor 44a is connected to a first test data line 46-1, a first electrode of the second test transistor 44b is connected to a second test data line 46-2, and a first electrode of the third test transistor 44c is connected to a third test data line 46-3. The second electrodes of the first test transistor 44a, the second test transistor 44b, and the third test transistor 44c are respectively connected to different data lines DL in the display area. That is, a second electrode of the first test transistor 44a is connected to one data line DL, a second electrode of the second test transistor 44b is connected to another data line DL, and a second electrode of the third test transistor 44c is connected to another data line DL. In this way, through the test control signal wire 45, turn-on of the three test transistors in the test circuit 40 can be controlled, and signals of different test data lines can be controlled to be written into different data lines DL. During the test, a conduction signal is provided to the test control signal line 45, and required test data signals are provided to a plurality of test data lines respectively, so that a plurality of data lines in the display area can obtain the test data signals to achieve detection.

In some examples, color(s) of sub-pixels connected with each data line may be the same. During the test, a same test data signal is provided to the data lines corresponding to sub-pixels of a same color, so that these sub-pixels can display in the same way, and determine whether there is a defective sub-pixel from the color of the display image, and locate the defective sub-pixel.

FIG. 14A is a schematic plan view of a test circuit according to at least one embodiment of the present disclosure. FIG. 14 illustrates two test circuits arranged along the first direction X. In some examples, as shown in FIG. 14, a first test transistor 44a, a second test transistor 44b, and a third test transistor 44c of the test circuit may be arranged sequentially along the second direction Y. A test control signal line 45, a first test data line 46-1, a second test data line 46-2, and a third test data line 46-3 may be arranged sequentially along the second direction Y and extend at least in the first direction X. The test control signal line 45, the first test data line 46-1, the second test data line 46-2, and the third test data line 46-3 may be located in the first source-drain metal layer. Active layers of the three test transistors of the test circuit and active layers of transistors of a pixel circuit of the sub-pixel may be disposed in a same layer. A gate of the first test transistor 44a, a gate of the second test transistor 44b, and a gate of the third test transistor 44c of a test circuit may be formed into an integral structure and are located at in the first gate metal layer, and may be electrically connected to the test control signal line 45 located in the first source-drain metal layer. A first electrode of the first test transistor 44a may be electrically connected to the first test data line 46-1 located in the first source-drain metal layer, and a second electrode of the first test transistor 44a may be electrically connected to a data line DL3 located at the second gate metal layer through a connection electrode located in the first source-drain metal layer. A first electrode of the second test transistor 44b may be electrically connected to the second test data line 46-2 located in the first source-drain metal layer, and a second electrode of the second test transistor 44b may be electrically connected to a data line DL2 located in the first gate metal layer through a connection electrode located in the first source-drain metal layer. A first electrode of the third test transistor 44c may be electrically connected to the third test data line 46-3 located in the first source-drain metal layer, and a second electrode of the third test transistor 44c may be electrically connected to a data line DL1 located in the second gate metal layer through a connection electrode located in the first source-drain metal layer. The three test transistors of another test circuit may be electrically connected to data lines DL4, DL5 and DL6, respectively.

In some examples, the test control signal line electrically connected to the test circuit group and the three test data lines may each be electrically connected to an aging pin transmitting a same signal in the aging pin group through a first test connection line. The test control signal line and the three test data lines electrically connected to the test circuit group can be electrically connected to a test circuit in an adjacent test circuit group through respective test circuit connection lines.

FIG. 15A is another schematic diagram of local distribution of the aging pin group 31g and the bonding pin group 41a in FIG. 6. FIG. 15B is another schematic diagram of local distribution of the aging pin group 31h and the bonding pin group 41d in FIG. 6. FIG. 16 is another partial schematic view of the bonding pin region and the first cutting region of FIG. 6.

In some examples, as shown in FIGS. 15A, 15B, and 16, the aging pin groups 31g and 31h may each include a first aging pin group 311 and a second aging pin group 312. The first aging pin group 311 may be located on a side of the second aging pin group 312 close to an edge of the display substrate. In this example, the first aging pin groups 311 may be provided in the aging pin groups 31g and 31h, and remaining aging pin groups may include only the second aging pin groups. A first aging pin in an aging pin group may be electrically connected to a first signal transmission line through a first adapter line, and electrically connected to a gate drive circuit located in the bezel region through the first signal transmission line. For rest of the description, reference may be made to the description of the foregoing embodiments, thus details will not be repeated here.

In the example illustrated in FIGS. 15A to 16, by arranging the first aging pins at left and right edges of the bonding area, it is possible to facilitate the first aging pins to provide signals to gate drive circuits in the bezel region (for example, the left and right bezels). However, since the EAC cutting process has clear requirements on distances between aging pins and a rough cutting line, it will easily cause that there is no enough space for a certain quantity (for example, 17, 21, 25 or more) of pins at the left and right edges of the bonding pin region. Based on this, in the example shown in FIGS. 7A to 12B, by arranging the first aging pin between the first and second bonding pin groups and between the last two bonding pin groups in the bonding pin region, it is possible to solve the problem of aging pin arrangement when space at the left and right edges of the bonding pin region is insufficient.

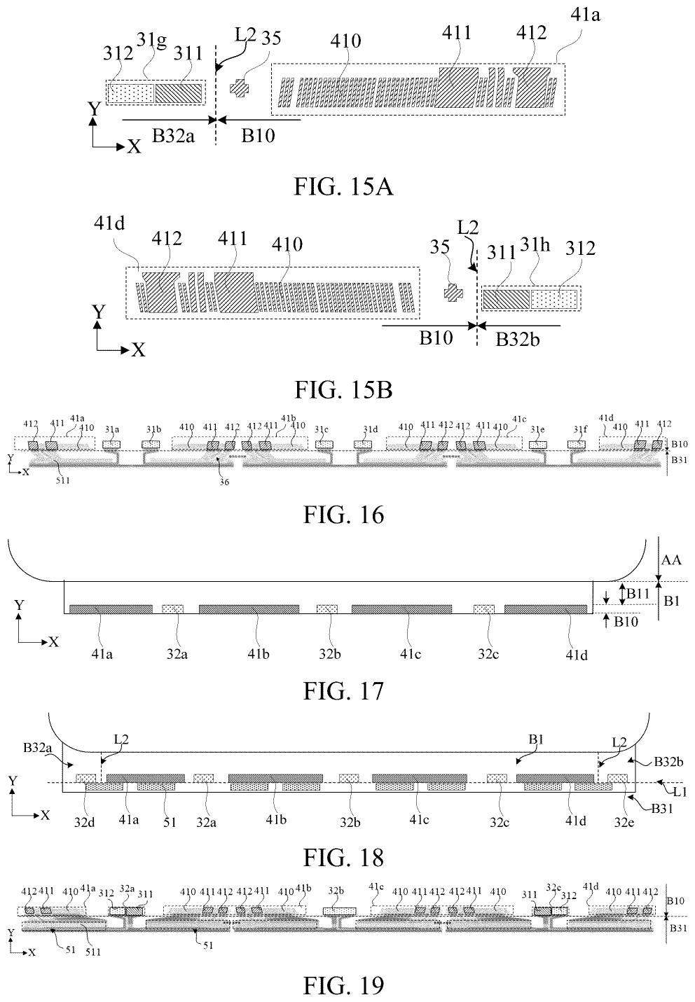

FIG. 17 is a schematic view of a bonding area of a display substrate according to at least one embodiment of the present disclosure. In some examples, as shown in FIG. 17, the bonding pin region B10 may include a plurality of aging pin groups (e.g., three aging pin groups 32a to 32c arranged along the first direction X) and a plurality of bonding pin groups (e.g., four bonding pin groups 41a to 41d arranged along the first direction X). A plurality of aging pin groups and a plurality of bonding pin groups may be alternately arranged along the first direction X and arranged side by side. For example, one aging pin group may be provided between two adjacent bonding pin groups. For example, the aging pin group 32a may be provided between the first bonding pin group 41a and a second bonding pin group 41b, an aging pin group 32b may be provided between the second bonding pin group 41b and a third bonding pin group 41c, and the aging pin group 32c may be provided between the third bonding pin group 41c and the third bonding pin group 41d. However, in this embodiment, the quantity of bonding pin groups is not limited.

FIG. 18 is a partial schematic view of a display mother plate according to at least one embodiment of the present disclosure. The display substrate shown in FIG. 17 can be obtained after the display mother plate shown in FIG. 18 is cut. In some examples, as shown in FIG. 18, a first cutting region B31 may be provided with a plurality of test pin groups 51. A second cutting region B32a may be provided with an aging pin group 32d, and the second cutting region B32b may be provided with an aging pin group 32e.

FIG. 19 is a partial schematic view of the bonding pin region and the first cutting region in FIG. 18. In some examples, as shown in FIG. 19, the aging pin groups 32a and 32c may each include a first aging pin group 311 and a second aging pin group 312. The second aging pin 312 may be located on a side of the first aging pin group 311 close to an edge of the display substrate. The aging pin group 32b may include a second aging pin group. As shown in FIG. 18, the aging pin groups 32d and 32e may include a second aging pin group. For example, the aging pin group 32a and the aging pin group 32c may each include 17 pins respectively (for example, including nine first aging pins and eight second aging pins), and the aging pin groups 32b, 32d, and 32e may each include eight pins respectively (for example, including eight second aging pins). In this embodiment, the quantity of pins is not limited. For rest of the description of the display substrate of this embodiment, reference may be made to the description of the foregoing embodiments, thus details will not be repeated here.

Compared with the examples shown in FIGS. 7A to 12B, one aging pin group is arranged between adjacent bonding pin groups in this example, which is equivalent to combining two second aging pin groups into one aging pin group in the previous example, and the space occupied by the second aging pins in the bonding pin region can be reduced, thereby improving the situation that the arrangement space for aging pins in the bonding area is insufficient.

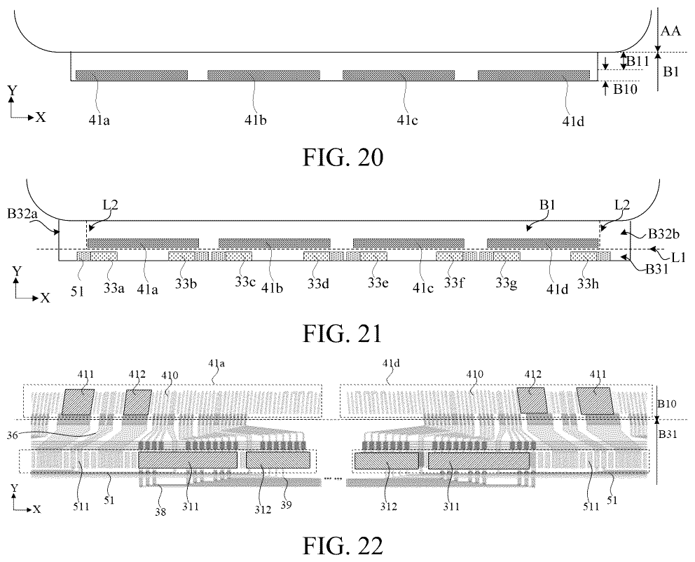

FIG. 20 is a schematic view of a bonding area of a display substrate according to at least one embodiment of the present disclosure. In some examples, as shown in FIG. 20, the bonding pin region B10 may include a plurality of bonding pin groups (e.g., four bonding pin groups 41a to 41d). The plurality of bonding pin groups may be arranged side by side in sequence along the first direction X. Each bonding pin group may be configured to be bonded to one circuit board.

FIG. 21 is a partial schematic view of a display mother plate according to at least one embodiment of the present disclosure. FIG. 22 is a partial schematic view of a bonding pin region and a first cutting region in FIG. 21. The display substrate shown in FIG. 20 can be obtained after the display mother plate shown in FIG. 21 is cut. In some examples, as shown in FIGS. 21 and 22, each bonding pin group may include a plurality of access pins 410, a first power supply pin 411, and a second power supply pin 412. The first power supply pin 411 and the second power supply pin 412 may be configured to be used as aging pins during the aging stage to transmit a power supply signal during the aging stage.

In some examples, as shown in FIGS. 21 and 22, the first cutting region B31 may be provided with a plurality of test pin groups 51. Each bonding pin group may be electrically connected to two corresponding test pin groups 51. For example, the bonding pin group 41a is electrically connected to the two corresponding test pin groups 51. Each test pin group 51 may include a plurality of test pins 511. The plurality of test pins 511 may be divided into three parts, the first part of pins may form a first aging pin group 311 as first aging pins, the second part of pins may form a second aging pin group 312 as the second aging pins, the first part of pins and the second part of pins may be configured to be used in the test phase and the aging stage, and the third part of pins may be configured to be used only in the test phase. The test pins 511 may be electrically connected to corresponding bonding pins via first connection lines 36. A plurality of pins transmitting a same signal in the first aging pin groups may be electrically connected through a second connection line 38, and a plurality of pins transmitting a same signal in the second aging pin group may be electrically connected through a third connection line 39. For rest of the description of this embodiment, reference may be made to the description of the foregoing embodiments, thus details will not be repeated here.

In this example, sharing part of the test pins in the test pin group as aging pins can reduce the space occupied by aging pins in the bonding pin region and improve the situation that there is insufficient arrangement space for aging pins in the bonding pin region.

In some exemplary embodiments, arrangement positions of aging pins in the above embodiments may be combined. For example, a part of the aging pins may be located in the bonding pin region, and another part of the aging pins may be located in the first cutting region and shared with the test pins. However, this embodiment is not limited thereto.

This embodiment further provides a display substrate, including a base substrate, a plurality of sub-pixels, a plurality of data lines, a plurality of driver chip pin groups, a plurality of aging pin groups, and a plurality of bonding pin groups. The base substrate includes a display area and a bonding area on one side of the display area. The plurality of sub-pixels are located in the display area. The plurality of data lines are located in the display area and the bonding area, and the plurality of data lines are electrically connected to the plurality of sub-pixels. A plurality of driver chip pin groups are located in the bonding area and arranged along a first direction, connected with a plurality of data lines, and the plurality of driver chip pin groups are configured to be bonded to a driver chip. A plurality of aging pin groups and a plurality of bonding pin groups are located in the bonding area and at a side of the plurality of driver chip pin groups away from the display area, and the plurality of bonding pin groups are arranged along the first direction and connected with the plurality of driver chip pin groups through pin connection lines. At least one aging pin group is provided between two adjacent bonding pin groups.

In the display substrate according to this embodiment, by arranging an aging pin group between a plurality of bonding pins in the bonding area, the aging pins can be arranged in the bonding area, thereby improving the situation that the arrangement space of the aging pins in the bonding area is insufficient.

In some exemplary embodiments, a plurality of aging pin groups may be arranged along the first direction, and the plurality of aging pin groups and the plurality of bonding pin groups are arranged side by side along the first direction.

In some exemplary embodiments, the plurality of bonding pin groups and the plurality of driver chip pin groups may be one-to-one electrically connected. In this example, the quantity of bonding pin groups may be the same as the quantity of driver chip pin groups.

In some exemplary embodiments, the plurality of driver chip pin groups includes m driver chip pin groups, with m being a positive integer greater than or equal to 3, and the plurality of driver chip pin groups include a first driver chip pin group, a second driver chip pin group, and an m-th driver chip pin group in the first direction. The display substrate further includes a bezel area located on another side of the display area. The bezel area is provided with a gate drive circuit configured to be electrically connected to a first driver chip pin group and an m-th driver chip pin group through a first signal transmission line. In some examples, m may be 4. For example, a gate drive circuit in the left bezel can be connected to a pin in the first driver chip pin group through a first signal transmission line, and a gate drive circuit in the right bezel can be connected to a pin in the fourth driver chip pin group through a first signal transmission line. The connection mode of the first signal transmission lines of this example can avoid large interference to other wirings.

The structure of the display substrate according to this embodiment may be referred to descriptions of the aforementioned embodiments, and will not be repeated here.

A display apparatus is further provided in at least an embodiment of the present disclosure, which includes the display substrate as described above. The display apparatus may be any product or component with a display function, such as a mobile phone, a tablet computer, a television, a display, a laptop computer, a digital photo frame, or a navigator.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, which shall all fall in the scope of the claims of the present application.

1. A display substrate, comprising:
a base substrate comprising a display area and a bonding area located at a side of the display area;
a plurality of sub-pixels located in the display area;
a plurality of data lines located in the display area and the bonding area, the plurality of data lines being electrically connected to the plurality of sub-pixels;
a plurality of test circuit groups arranged along a first direction, the plurality of test circuit groups being electrically connected to the plurality of data lines;
a plurality of aging pin groups and a plurality of bonding pin groups located in the bonding area and on a side of the plurality of test circuit groups away from the display area;
wherein the plurality of bonding pin groups are arranged along the first direction, and at least one aging pin group is arranged between two adjacent bonding pin groups; each bonding pin group is configured to be bonded to at least one circuit board, and each test circuit group is configured to be connected to at least one aging pin group during a test stage.

2. The display substrate according to claim 1, wherein the plurality of bonding pin groups comprise n bonding pin groups, n being a positive integer greater than or equal to 3, the plurality of bonding pin groups comprising a first bonding pin group, a second bonding pin group . . . and an n-th bonding pin group sequentially in the first direction, wherein an aging pin group comprised between the first bonding pin group and the second bonding pin group comprises: a plurality of first aging pins arranged along the first direction continuously and configured to transmit a gate drive control signal;
wherein an aging pin group comprised between the n-th bonding pin group and an (n-1)-th bonding pin group comprises a plurality of first aging pins arranged along the first direction continuously and configured to transmit a gate drive control signal.

3. The display substrate according to claim 2, further comprising: a bezel area located at a remaining side of the display area; wherein the bezel area is provided with a gate drive circuit configured to be connected to the first aging pins in the aging pin group between the first bonding pin group and the second bonding pin group and the aging pin group between the n-th bonding pin group and the (n-1)-th bonding pin group during the test stage.

4. The display substrate according to claim 1, wherein one or two aging pin groups are provided between two adjacent bonding pin groups.

5. The display substrate according to claim 1, wherein each of the plurality of aging pin groups comprises a plurality of second aging pins arranged along the first direction continuously and configured to transmit a direct current signal.

6. The display substrate according to claim 1, wherein at least one aging pin group of the plurality of aging pin groups comprises a plurality of first aging pins arranged along the first direction continuously and configured to transmit a gate drive control signal and a plurality of second aging pins arranged along the first direction continuously and configured to transmit a direct current signal, and the plurality of second aging pins are located on one side of the plurality of first aging pins close to an edge of the display substrate.

7. The display substrate according to claim 2, wherein a first aging pin of at least one aging pin group of the plurality of aging pin groups is configured to be electrically connected to a first aging pin transmitting a same signal in other aging pin groups during the test stage.

8. The display substrate according to claim 5, wherein second aging pins transmitting a same signal in the plurality of aging pin groups are configured to be electrically connected during the test stage.

9. The display substrate according to claim 1, wherein the plurality of test circuit groups are connected by a test circuit connection line.

10. The display substrate according to claim 1, wherein at least one test circuit group of the plurality of test circuit groups is configured to be connected to two aging pin groups during the test stage, and the two aging pin groups are located on two sides of the at least one test circuit group.

11. The display substrate according to claim 10, wherein pins transmitting a same signal in aging pin groups electrically connected to different test circuit groups and arranged adjacent to each other are configured to be electrically connected during the test stage.

12. The display substrate according to claim 10, wherein pins transmitting a same signal in aging pin groups electrically connected to a same test circuit group and arranged adjacent to each other are configured to be electrically connected during the test stage.

13. The display substrate according to claim 1, wherein the plurality of aging pin groups are arranged along the first direction, and the plurality of aging pin groups and the plurality of bonding pin groups are arranged side by side along the first direction.

14. The display substrate according to claim 1, wherein each of the plurality of bonding pin groups comprises a plurality of access pins, at least one first power supply pin, and at least one second power supply pin arranged along the first direction; the at least one first power supply pin and the at least one second power supply pin in each bonding pin group are configured to be used as aging pins during an aging stage, and each bonding pin group is configured to be bonded to at least one circuit board after the aging stage.

15. A display apparatus, comprising the display substrate according to claim 1.

16. A display substrate, comprising:
a base substrate comprising a display area and a bonding area located at a side of the display area;
a plurality of sub-pixels located in the display area;
a plurality of data lines located in the display area and the bonding area, the plurality of data lines being electrically connected to the plurality of sub-pixels;
a plurality of driver chip pin groups located in the bonding area and arranged along a first direction, connected with the plurality of data lines, and configured to be bonded to a driver chip;
a plurality of aging pin groups and a plurality of bonding pin groups located in the bonding area and on a side of the plurality of driver chip pin groups away from the display area, wherein the plurality of bonding pin groups are arranged along the first direction, and are connected with the plurality of driver chip pin groups through pin connection lines, and at least one aging pin group is arranged between two adjacent bonding pin groups.

17. The display substrate according to claim 16, wherein the plurality of aging pin groups are arranged along the first direction, and the plurality of aging pin groups and the plurality of bonding pin groups are arranged side by side along the first direction.

18. The display substrate according to claim 16, wherein the plurality of bonding pin groups and the plurality of driver chip pin groups are correspondingly in one-to-one electrical connection.

19. The display substrate according to claim 16, wherein the plurality of driver chip pin groups comprise m driver chip pin groups, with m being a positive integer greater than or equal to 3, and the plurality of driver chip pin groups comprise a first driver chip pin group, a second driver chip pin group . . . and an m-th driver chip pin group in the first direction;
the display substrate further comprises a bezel area located at a remaining side of the display area, the bezel area is provided with a gate drive circuit configured to be electrically connected with the first driver chip pin group and the m-th driver chip pin group through a first signal transmission line.

20. The display substrate according to claim 16, wherein one or two aging pin groups are provided between two adjacent bonding pin groups.
